(19) United States
(12) Patent Application Publication
(10) Pub. No.: US 2013/0180579 A1
(43) Pub. Date: Jul. 18, 2013

(54) PHOTOVOLTAIC DEVICE HAVING AN ABSORBER MULTILAYER AND METHOD OF MANUFACTURING THE SAME

(71) Applicant: FIRST SOLAR, INC, Perrysburg, OH (US)

(72) Inventors: Changming Jin, Sylvania, OH (US); Xilin Peng, Bloomington, MN (US); Rick C. Powell, Ann Arbor, MI (US); Aaron Roggelin, Millbury, OH (US); Gang Xiong, Santa Clara, CA (US)

(73) Assignee: FIRST SOLAR, INC, Perrysburg, OH (US)

(21) Appl. No.: 13/743,440

(22) Filed: Jan. 17, 2013

Related U.S. Application Data
(60) Provisional application No. 61/587,171, filed on Jan. 17, 2012.

(51) Int. Cl. H01L 31/075; H01L 31/18

(52) U.S. Cl. CPC H01L 31/075; H01L 31/1828
USPC 136/255; 438/87

(57) ABSTRACT

A photovoltaic device having an absorber multilayer and methods of manufacturing the same are described. The absorber multilayer, which is formed adjacent to a window layer, may include a doped first cadmium telluride layer which contains a first dopant and an intrinsic second cadmium telluride layer. The absorber multilayer may further include at least a third cadmium telluride layer formed adjacent to a back contact. The at least third cadmium telluride layer may include doped or intrinsic cadmium telluride.

### CLAIM OF PRIORITY

This application claims priority under 35 U.S.C. §119(e) to U.S. Provisional Patent Application Ser. No. 61/587,171 filed on Jan. 17, 2012, which is hereby incorporated by reference in its entirety.

### TECHNICAL FIELD

Disclosed embodiments relate to the field of photovoltaic devices, which include photovoltaic cells and photovoltaic modules containing a plurality of cells, and method of manufacturing thereof.

### BACKGROUND

Photovoltaic devices such as photovoltaic modules or cells may use a plurality of semiconductor materials as fundamental layers in producing electric current. These fundamental layers may include an n-type semiconductor window layer (e.g., cadmium sulfide), and a p-type semiconductor absorber layer (e.g., cadmium telluride). When photons pass through the n-type window layer and are absorbed within the p-type absorber layer, electron-hole pairs are generated. The interface of the n-type window layer and the p-type absorber layer creates an electric field which separates such electron-hole pairs to produce electric current.

Photo-conversion efficiency is the proportion of incident photons that the photovoltaic device converts into electric current. Various loss mechanisms can potentially diminish photo-conversion efficiency. For instance, photons absorbed within the window layer cannot be converted into electric current. In addition, electrons can be lost through a process called recombination, in which excited electrons in the conduction band which would otherwise generate electric current are lost when such electrons fall from the conduction band back into an empty state in the valence band called a hole, or a position in the valence band where an electron could exist.

Mitigating recombination improves the photo-conversion efficiency of photovoltaic devices. A band gap is the difference in energy between electron orbitals in the valence band and electron orbitals in the conduction band. This difference is the amount of electromagnetic energy required to excite an electron to the conduction band to create a mobile charge carrier capable of contributing to current flow in the photovoltaic device. Substances with wide band gaps are generally insulators and those with narrower band gaps are typically semiconductors. If an electron is no longer in the conduction band, it will no longer contribute to current flow. Thus, potential recombination interferes with current flow in the device. Generally, a wider band gap adjacent to a back contact, which can interface with the p-type absorber layer, can help repel electrons away from the back contact to avoid recombination.

To maximize the photo-conversion efficiency of photovoltaic devices, it is desirable to minimize photon absorption within the window layer and to mitigate recombination. A method of mitigating such potential loss mechanisms and promoting photo-conversion efficiency using an absorber layer is particularly desirable.

### DESCRIPTION OF DRAWINGS

FIG. 1 is a cross-sectional view of a conventional photovoltaic device.

FIG. 2A is a cross-sectional view of a photovoltaic device according to a first embodiment at a stage of processing following formation of a cadmium telluride multilayer.

FIG. 2B is a cross-sectional view of the photovoltaic device of FIG. 2A at a stage of processing subsequent to that of FIG. 2A.

FIG. 3A is a cross-sectional view of a photovoltaic device according to a second embodiment at a stage of processing following formation of a cadmium telluride multilayer.

FIG. 3B is a cross-sectional view of the photovoltaic device of FIG. 3A at a stage of processing subsequent to that of FIG. 3A.

FIG. 4A is a cross-sectional view of a photovoltaic device according to a third embodiment at a stage of processing following formation of a cadmium telluride multilayer.

FIG. 4B is a cross-sectional view of the photovoltaic device of FIG. 4A at a stage of processing subsequent to that of FIG. 4A.

FIG. 5A is a cross-sectional view of a photovoltaic device according to a fourth embodiment at a stage of processing following formation of a cadmium telluride multilayer.

FIG. 5B is a cross-sectional view of the photovoltaic device of FIG. 5A at a stage of processing subsequent to that of FIG. 5A.

FIG. 6A is a cross-sectional view of a photovoltaic device according to a fifth embodiment at a stage of processing following formation of a cadmium telluride multilayer.

FIG. 6B is a cross-sectional view of the photovoltaic device of FIG. 6A at a stage of processing subsequent to that of FIG. 6A.

FIG. 7 is a schematic of a manufacturing process for a photovoltaic device having a cadmium telluride multilayer.

### DETAILED DESCRIPTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or procedural changes may be made to the specific embodiments disclosed without departing from the spirit and scope of the invention.

Embodiments described herein provide for a photovoltaic device having a multilayered fundamental layer and methods of manufacturing the same. The multilayered fundamental layer can mitigate photon absorption and maximize the photo-conversion efficiency within the photovoltaic device through recombination mitigation. In the disclosed embodiments, the multilayered fundamental layer used is the absorber layer. The multilayered absorber layer (or absorber multilayer) includes at least a doped first cadmium telluride layer and an intrinsic (i.e. substantially free of dopant material at formation) second cadmium telluride layer. Note that, although embodiments described herein include a multilayered absorber layer having a doped cadmium telluride first layer and an intrinsic cadmium telluride second layer, the invention is not thus restricted. Any method that can be used to mitigate photon absorption and maximize photo-conversion efficiency is well within the realm of the invention. For example and as described below, more than one doped absorber layer may be used in conjunction with an intrinsic absorber layer. Hence, the use of a multilayered absorber layer having a doped first cadmium telluride layer and an intrinsic second cadmium telluride layer is only for illustrative purposes.

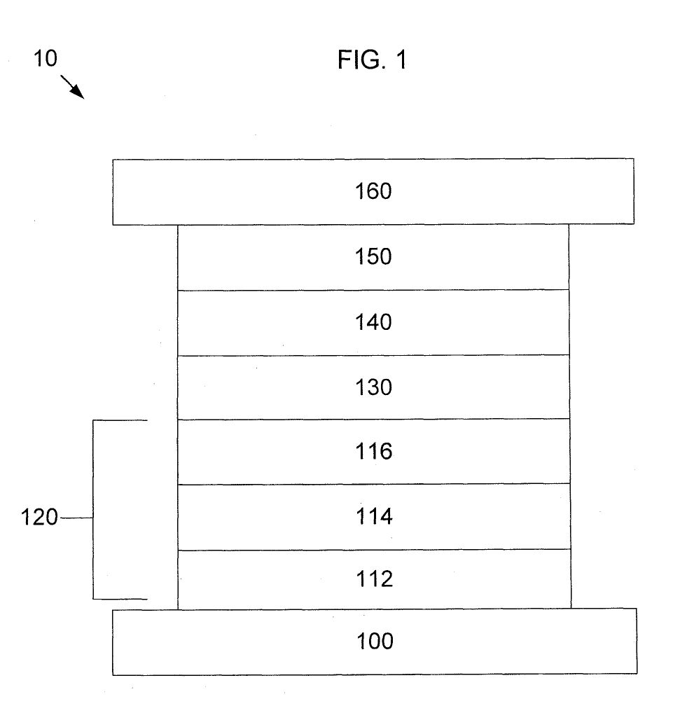

Referring to FIG. 1, by way of example, a conventional photovoltaic device 10 can be formed sequentially in a stack on a substrate 100, for example, soda-lime glass or other suitable glass or material. Because substrate 100 is not conductive, device 10 can include a front contact 120, which can include a multi-layered transparent conductive oxide (TCO) stack with several functional layers including a barrier layer 112 to protect the semiconductor layers from potential contaminants from substrate 100, a TCO layer 114 to provide for high optical transmission and low electrical resistance, and a buffer layer 116 to mitigate potential irregularities during the subsequent formation of the semiconductor layers, for example. The barrier layer 112 may include, for example, silicon dioxide. The TCO layer 114 may include any suitable transparent conductive oxide, for example, cadmium stannate or cadmium tin oxide. The buffer layer 116 may include various suitable materials, for example, tin oxide (e.g., tin (IV) oxide), zinc tin oxide, zinc oxide or zinc magnesium oxide.

The semiconductor layers can include an n-type semiconductor window layer 130, such as a cadmium sulfide layer, formed on the front contact 120 and a p-type semiconductor absorber layer 140, such as a cadmium telluride layer, formed on the semiconductor window layer 130. The window layer 130 can allow the penetration of solar energy to the absorber layer 140, where the photon energy is converted into electrical energy. Back contact 150 is formed over absorber layer 140. Back contact 150 may be one or more highly conductive materials, for example, molybdenum, aluminum, copper, silver, gold, or any combination thereof, providing a low-resistance ohmic contact. Front and back contacts 120, 150 may serve as electrodes for transporting photocurrent away from device 10. Back support 160, which may be glass, is formed over back contact 150 to protect device 10 from external hazards. Each layer may in turn include more than one layer or film. Additionally, each layer can cover all or a portion of the device and/or all or a portion of the layer or substrate underlying the layer. For example, a “layer” can include any amount of any material that contacts all or a portion of a surface. It should be noted and appreciated that any of the aforementioned layers may include multiple layers, and that “on” or “onto” does not mean “directly on,” such that in some embodiments, one or more additional layers may be positioned between the layers depicted.

Photons absorbed by the window layer 130 cannot be absorbed by the absorber layer 140 which decreases the photo-conversion efficiency of the device 10. One approach to mitigating light absorption within the window layer 130, for example, is to decrease its thickness at deposition. However, this has disadvantages. For example, a window layer thickness that is less than 300 angstroms (typical thicknesses range from 300 angstroms to 750 angstroms) is so thin that the window layer 130 may have discontinuities in it. For instance, the window layer 130 may provide only about 30% to about 70% coverage of the front contact 120. Such limited coverage of the front contact 120 results in intermittent and reduced contact between the window layer 130 and the absorber layer 140 which can disrupt the local, built-in electric field within the p-n junction formed at or near the interface of the p-type absorber and n-type window layers 140, 130. When the p-n junction is disrupted, non-uniform, unpredictable element diffusion across the p-n junction can occur which increases the risk of diminished electrical performance of the device 10. Current front contact 120 formation processes may generate a front contact 120 with a surface roughness that can contribute to an increased risk of discontinuity in the window layer 130 deposited thereon. Although the buffer layer 116 may smooth out some of this roughness, it may be insufficient when a thin window layer 130 is employed.

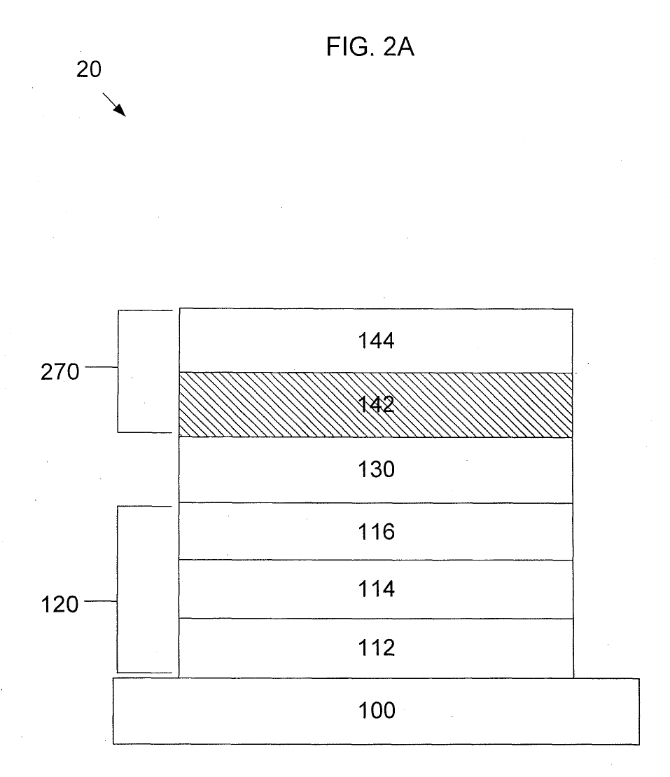

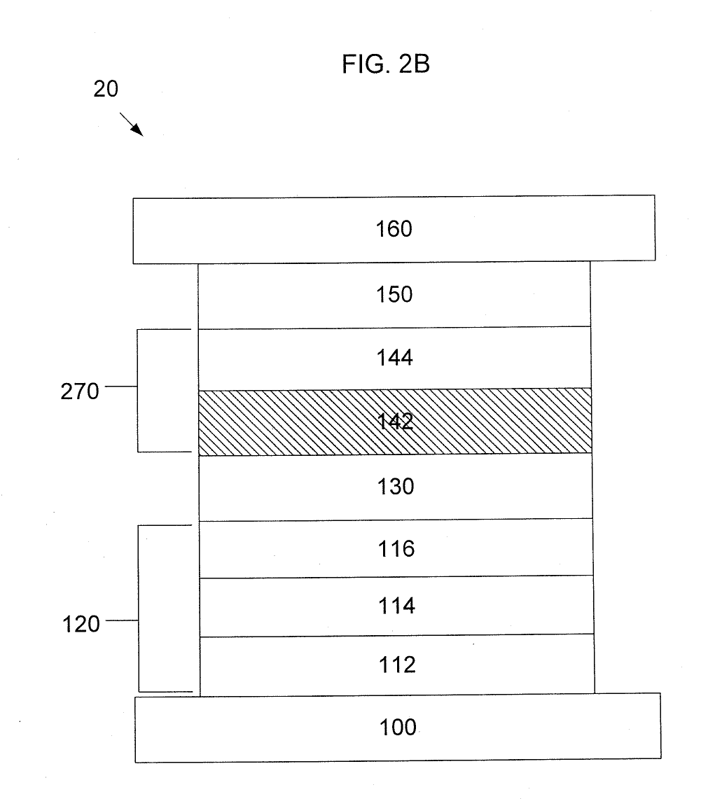

FIG. 2A illustrates a cross-sectional view of a first embodiment of a photovoltaic device 20 at a stage of processing after formation of a cadmium telluride absorber multilayer 270 in lieu of absorber layer 140 (FIG. 1). Referring to FIG. 2A, rather than depositing a window layer thinner than 300 angstroms, for example, window layer 130 is formed and its thickness is controlled in-situ to be greater than 300 angstroms, for example. Having the thickness of the window layer be at least 300 angstroms greatly minimizes the likelihood of discontinuities of the window layer over the front contact 120.

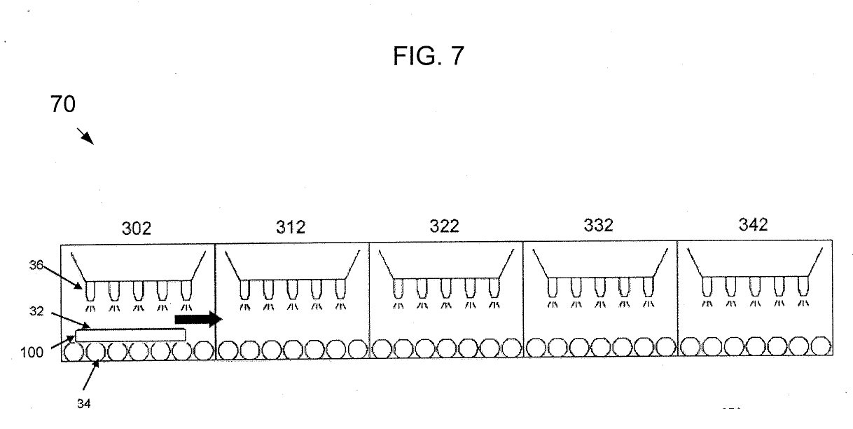

Cadmium telluride multilayer 270 includes a doped first cadmium telluride layer 142 and an intrinsic second cadmium telluride layer 144. Cadmium telluride multilayer 270 may be formed by vapor transport deposition, for example, as shown in FIG. 7 and discussed below.

The doped first cadmium telluride layer 142 can include a first dopant such as rubidium or silicon. More generally, the first dopant can include a Group I-A dopant material, for example, lithium, sodium, potassium, rubidium, cesium, a Group I-B dopant material, for example, copper, silver, gold, a Group V-A dopant material, for example, nitrogen, phosphorus, arsenic, antimony, bismuth, a Group IV-A dopant material, for example, silicon, germanium, tin and/or chlorine-containing compounds of the above dopant materials. The aforementioned dopant materials may be employed separately or in combination. Dopant material refers to material which may alter physical and/or electrical properties of the semiconductor layers 130, 270. Doped first cadmium telluride layer 142 and intrinsic second cadmium telluride layer 144 each may have a thickness of more than 1 nm, more than 10 nm, more than 20 nm, more than 1 μm, more than 5 μm, or less than 10 μm.

The first dopant may be incorporated into the doped first cadmium telluride layer 142 before, during or after deposition using any suitable doping technique. For example, the first dopant can be supplied from an incoming first dopant powder to be combined with a material to be deposited such as cadmium telluride, a carrier gas, or a directly doped powder such as a cadmium telluride-silicon powder. Alternatively, the first dopant can be supplied by diffusion from another layer of device 20. For example, a dopant material such as rubidium within one absorber layer can diffuse into another absorber layer. The first dopant concentration in the doped first cadmium telluride layer 142 can be about 10⁻⁷% to about 10% by weight, about 10⁻⁵% to about 10⁻³% by weight, about 10⁻³% to about 0.1% by weight, or about 0.1% to about 1% by weight. Depending on the rate of incorporation of the first dopant into doped first cadmium telluride layer 142, any suitable quantity of first dopant may be introduced into a deposition environment to achieve such concentration ranges, for example, more than 100 ppm, more than 250 ppm, more than 400 ppm, or less than 500 ppm.

After formation of cadmium telluride multilayer 270, one or more heat treatment steps may be performed before a back contact, such as back contact 150 in FIG. 1, is applied. Heat treatment entails heat treating semiconductor-coated substrate with a chlorine-containing compound, for example cadmium chloride, at between about 380° C. and about 800° C., between about 450° C. and about 800° C., or between about 380° C. and about 450° C., for about 20 minutes, for example. Cadmium chloride can be applied by various techniques, such as by solution spray, vapors, or atomized mist. Cadmium chloride diffuses preferentially through grain boundary areas of the intrinsic second and doped first cadmium telluride layers 144, 142, or interfaces where crystal grains or crystallites of different orientations meet. Grain boundary areas typically contain defects or other impurities, or atoms that have been disrupted from their original lattice sites, which can reduce conductivity. This process is known as healing or curing the grain boundary defects or imperfections within layers 144, 142. During heat treatment, recrystallization can occur, thereby enlarging cadmium telluride grains and making a more uniform doping distribution within the multilayer 270 possible. After healing layers 144, 142 through heat treatment, photon-generated carriers, for example electrons and holes, are more mobile and thus more easily collected.

FIG. 2B shows the device 20 after processing of the cadmium telluride multilayer 270 is completed. A back contact 150 and a back support 160, for example glass, are applied in sequence over the cadmium telluride multilayer 270. The back contact 150 may include one or more highly conductive materials. For example, the back contact 150 may include molybdenum, aluminum, copper, silver, gold, or any combination thereof.

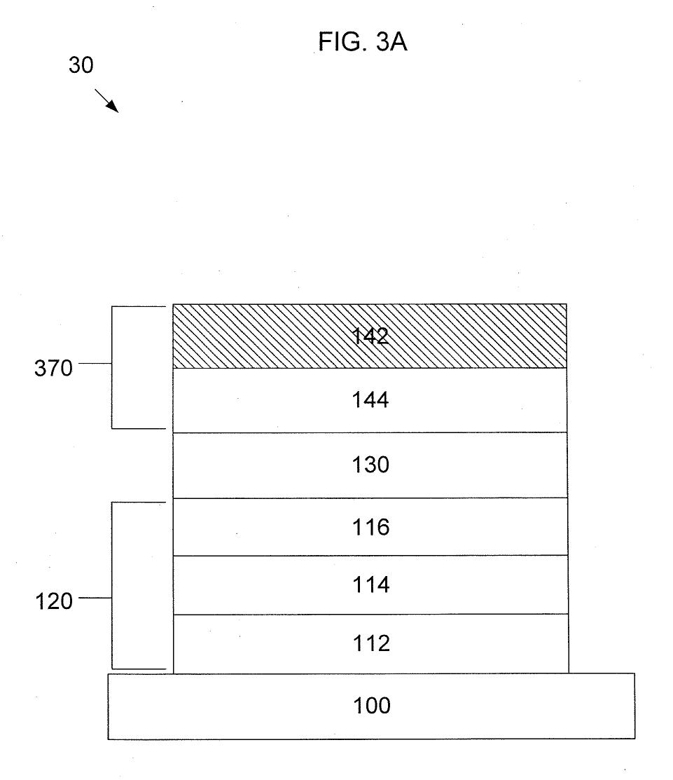

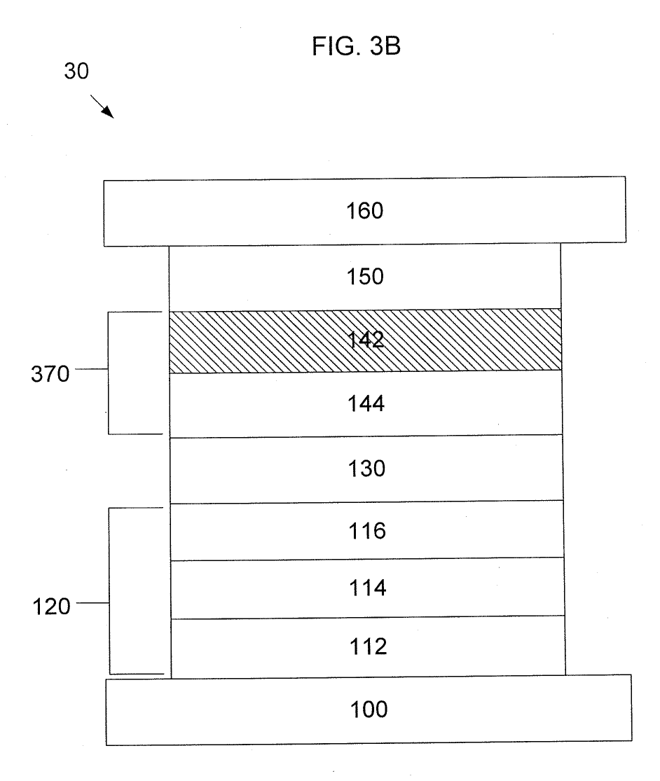

FIG. 3A illustrates a second embodiment of the invention. In FIG. 3A, a photovoltaic device 30 having a cadmium telluride multilayer 370, which is similar to the multilayer 270 of FIG. 2A, is depicted. However, in the cadmium telluride multilayer 370 of the present embodiment, the intrinsic second cadmium telluride layer 144 is formed between the window layer 130 and the doped first cadmium telluride layer 142.

The photovoltaic devices 20, 30 in FIGS. 2A and 3A can exhibit improved photo-conversion efficiency, for several reasons. First, during heat treatment, the first dopant forms intermediate compounds with low melting points, for example, a temperature below a heat treatment temperature of about 450° C., within the window layer 130, within the absorber multilayer 270, and at the interface between the window layer 130 and the absorber multilayer 270. The intermediate compounds melt during heat treatment. Such compounds enable control over window layer 130 thickness in-situ because the compounds cause the window layer 130 to flux or thin but still allow window layer 130 to remain continuous and conform to the front contact 120. This control is exercised through the positioning of the doped first cadmium telluride layer 142 relative to the window layer 130 and through the first dopant concentration in the absorber multilayer 270. Such control reduces window layer 130 thickness thus mitigating the absorption of photons therein.

Second, the FIG. 3A embodiment offers even greater control over window layer 130 thickness in-situ because the intrinsic second cadmium telluride layer 144 serves as a diffusion barrier between the window layer 130 and the doped first cadmium telluride layer 142. Therefore, the first dopant, rubidium or silicon for example, must diffuse through the intrinsic second cadmium telluride layer 144 to reach and react with the cadmium sulfide window layer 130 to form the aforementioned intermediate compounds. As a result, the window layer 130 is slower to flux. This delay can provide for a wider temperature process window and increased processing flexibility. For example, heat treatment can occur at higher temperatures before the intermediate compounds form and cause the window layer 130 to flux. Thus, window layer 130 thinning still occurs which provides for mitigation of photon absorption therein but it occurs in a delayed manner which allows for a more flexible temperature window during processing.

Third, continuing reference to the FIG. 3A embodiment, in addition to slowing first dopant diffusion into window layer 130 and for similar reasons, intrinsic second cadmium telluride layer 144 can also prevent excessive initial diffusion of first dopant outside of doped first cadmium telluride layer 142 thus providing for at least temporary first dopant concentration control within the doped first cadmium telluride layer 142. A high dopant concentration may increase the carrier concentration, e.g. electron, hole, across the p-n junction at or near the interface of the multilayer 370 and the window layer 130, which may lead to increased photo-conversion efficiency.

It has been found that, after heat treatment, cadmium telluride multilayers 270, 370 have had better grain structure and surface roughness. For example, cadmium telluride multilayers 270, 370, each having the doped first cadmium telluride layer 142 with first dopant silicon, demonstrated a surface roughness with a lower standard deviation compared to conventional p-type absorber layer 140 (FIG. 1).

FIG. 3B shows the device 30 after processing of the cadmium telluride multilayer 370 is completed. Back contact 150 and back support 160, applied in sequence over multilayer 370, are identical to such layers in the FIG. 2B embodiment.

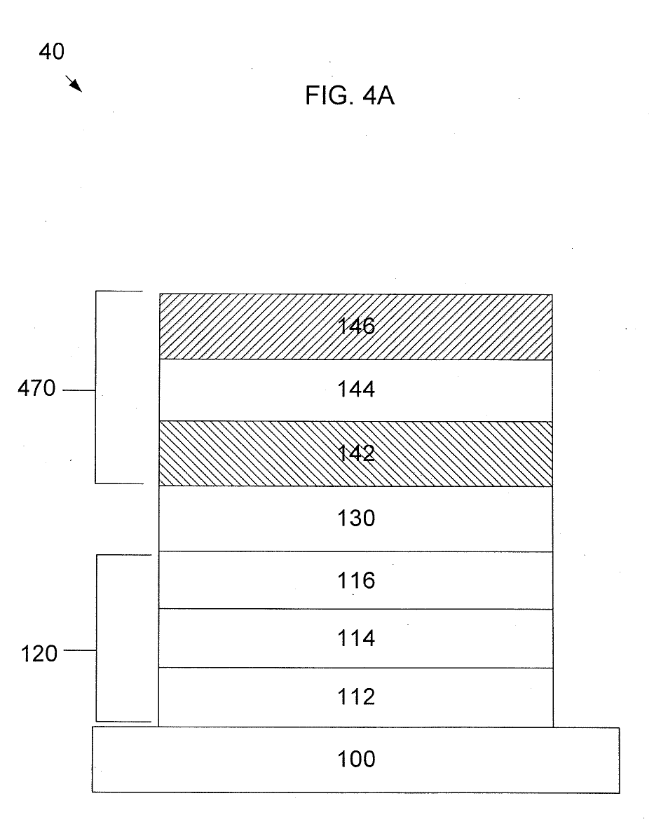

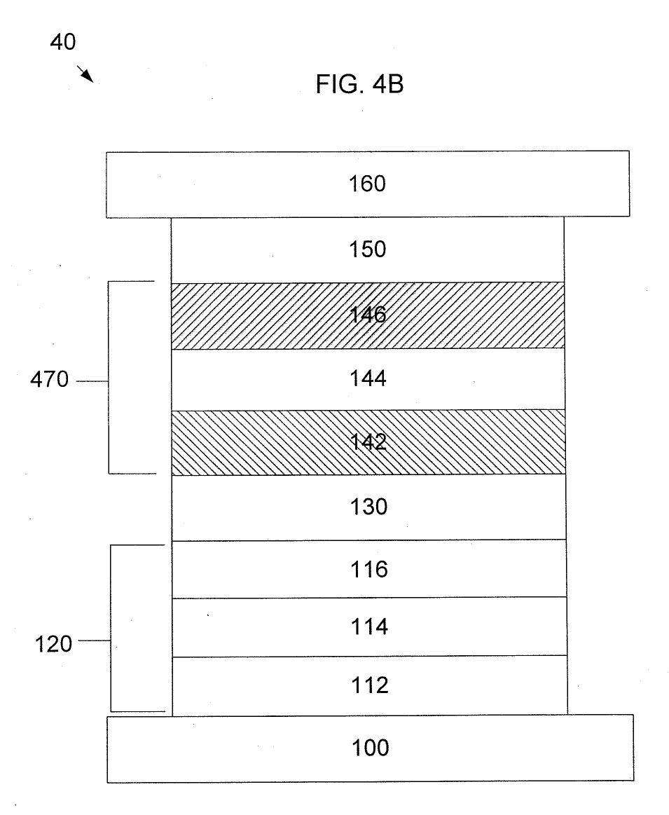

FIG. 4A illustrates a third embodiment of a photovoltaic device 40 having a cadmium telluride multilayer 470. After formation of the intrinsic second cadmium telluride layer 144 over doped first cadmium telluride layer 142, as described with respect to FIG. 2A, at least one doped third cadmium telluride layer 146 is formed over the intrinsic second cadmium telluride layer 144. Cadmium telluride multilayer 470 can be formed through vapor transport deposition, as shown in FIG. 7 and discussed below, for example. The at least one doped third cadmium telluride layer 146 can have any suitable thickness, for example, more than 1 nm, more than 10 nm, more than 20 nm, more than 1 μm, more than 5 μm, or less than 10 μm. The at least one doped third cadmium telluride layer 146 can include a second dopant, for example a Group I-B, V-A or VI-A dopant material such as copper, silver, gold, nitrogen, phosphorus, arsenic, antimony, bismuth, oxygen and/or chlorine-containing compounds of the above dopant materials. As discussed in more detail below, the second dopant can be different than the first dopant because the second dopant, for example copper, minimizes the contact resistance (i.e., the resistance of a material attributable to electrical leads and connections) between cadmium telluride multilayer 470 and back contact 150 and mitigates electron recombination at or near back contact 150. The second dopant may also be the same as the first dopant employed in the doped first cadmium telluride layer 142 or may include the first dopant. The second dopant can be incorporated into the at least one doped third cadmium telluride layer 146 using any suitable doping technique such as those described with respect to the first dopant (FIG. 2A). The concentration of the second dopant within the at least one doped third cadmium telluride layer 146 can be 10⁻⁷% to about 10% by weight, about 10⁻⁵ to about 10⁻³% by weight, about 10⁻³% to about 0.1% by weight, or about 0.1% to about 1% by weight.

FIG. 4B shows the device 40 after processing of the cadmium telluride multilayer 470 is completed. Back contact 150 and back support 160, applied in sequence over cadmium telluride multilayer 470, are identical to such layers in the FIG. 2B embodiment.

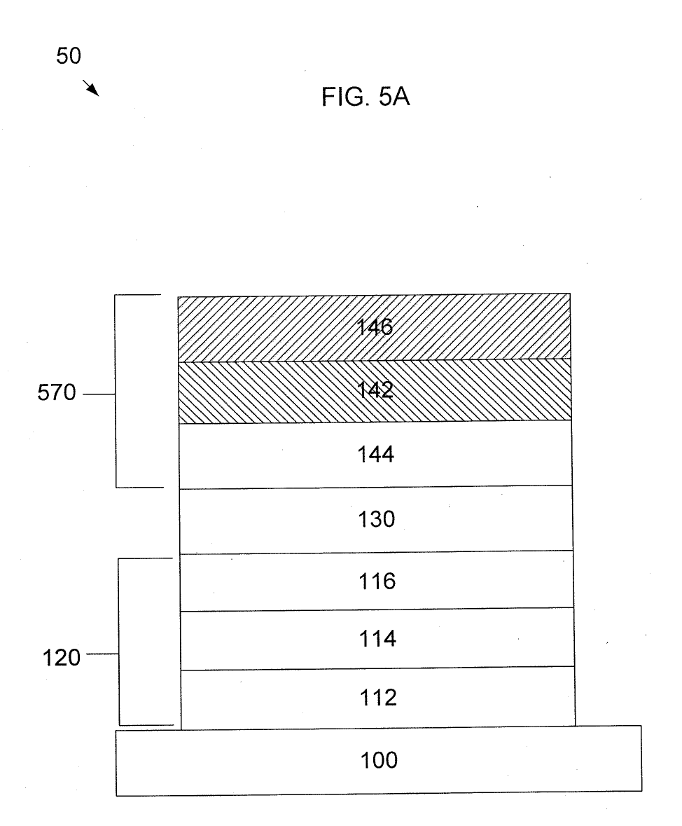

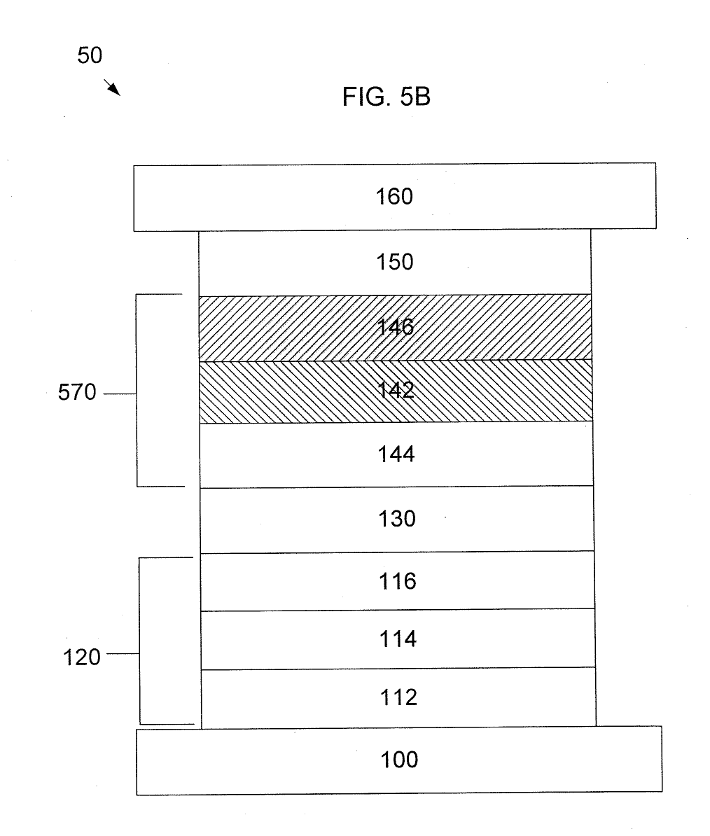

FIG. 5A illustrates a fourth embodiment of a photovoltaic device 50 in which the sequence of the doped first cadmium telluride layer 142 and the intrinsic second cadmium telluride layer 144 in FIG. 4A, can be reversed to form cadmium telluride multilayer 570. After formation of the doped first cadmium telluride layer 142, as described with respect to FIG. 3A, at least one doped third cadmium telluride layer 146 is formed over the doped first cadmium telluride layer 142. The advantages of the second (FIGS. 3A and 3B) and third (FIGS. 4A and 4B) embodiments discussed above, apply to the fourth embodiment.

FIG. 5B shows the device 50 after processing of the cadmium telluride multilayer 570 is completed. Back contact 150 and back support 160, applied in sequence over cadmium telluride multilayer 570, are identical to such layers in the FIG. 2B embodiment.

Photovoltaic devices 40, 50 with cadmium telluride multilayers 470, 570 present several advantages. The incorporation of the second dopant into the at least one doped third cadmium telluride layer 146 widens the band gap adjacent to the back contact 150 which, in turn, mitigates electron recombination at and near the back contact 150. When photons are absorbed within the multilayer 470, 570 electron-hole pairs generated in the multilayer 470, 570 are separated by the electric field at the p-n junction formed at or near the interface of the multilayer 470, 570 and the window layer 130. This creates electron flow toward such interface. However, some electrons still may diffuse toward the back contact 150 where they can recombine with holes. The at least one doped third cadmium telluride layer 146 treated with the second dopant bends, i.e. widens, the band gap near the back contact 150 to effectively repel electrons diffusing toward back contact 150 thus protecting against electron recombination and increasing photo-conversion efficiency. Additionally, the second dopant within the at least one doped third cadmium telluride layer 146 results in decreased contact resistance between the multilayer 470, 570 and the back contact 150 as compared to conventional absorber layer 140 (FIG. 1).

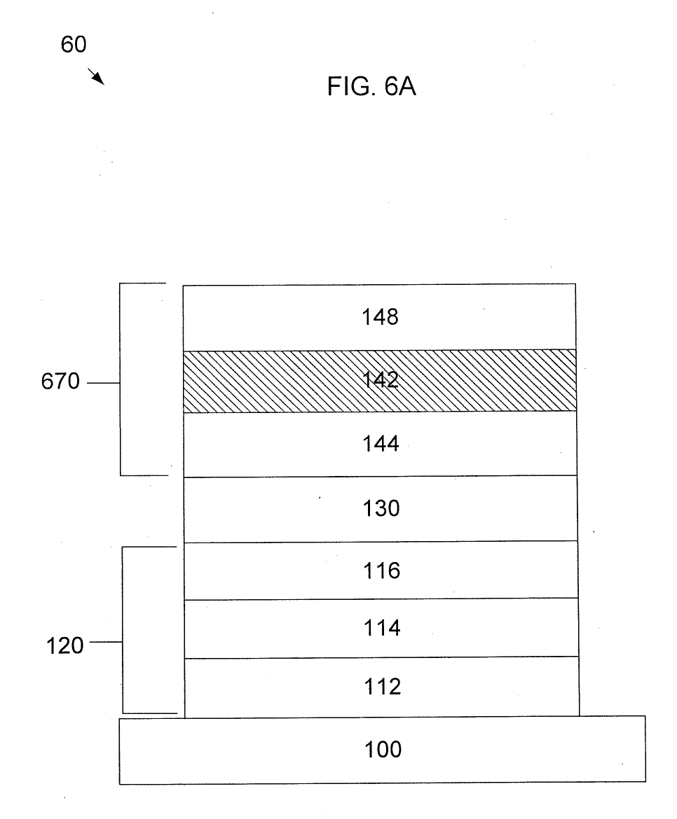

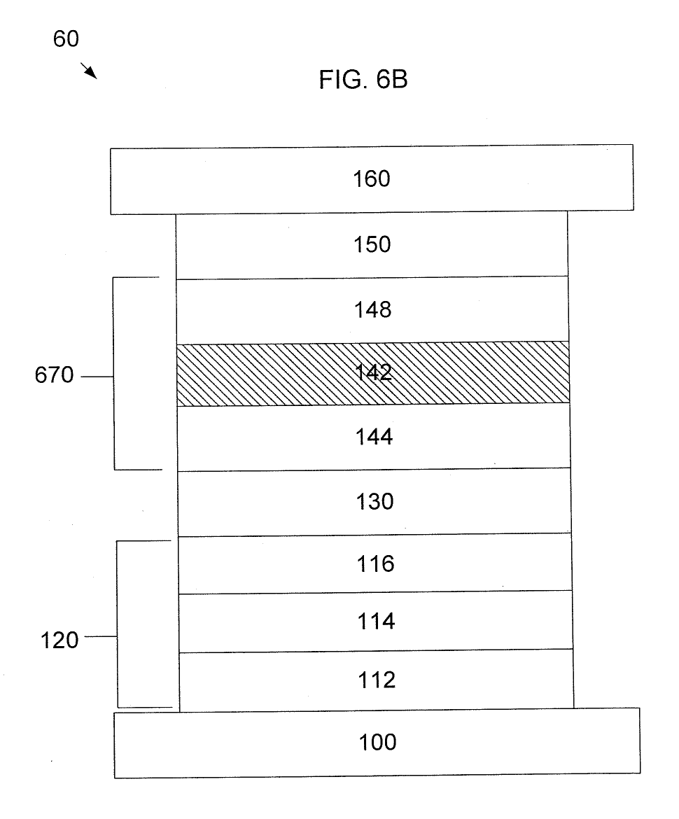

FIG. 6A illustrates a fifth embodiment of a photovoltaic device 60 having a cadmium telluride multilayer 670 which is similar to the cadmium telluride multilayer 570 in FIG. 5A except that at least one intrinsic third cadmium telluride layer 148 is substantially free of dopant material, similar to the intrinsic cadmium telluride layer 144. Forming the doped first telluride layer 142 between the two intrinsic cadmium telluride layers, i.e., 144 and 148, has advantages. First, as discussed above with respect to FIG. 3A, the sequence of layers 144, 142 provides for delayed or controlled fluxing of window layer 130 which mitigates photon absorption within window layer 130 and also provides for a wider process window, or renders window layer 130 less sensitive to fluxing at high processing temperatures. Also, intrinsic layers 144, 148 serve as dual diffusion barriers such that layers 144, 148 contain a desired amount of the first dopant within the doped first cadmium telluride layer 142 and prevent inter-diffusion up-and-down to back contact 150 and front contact 120 thus providing for dopant concentration control within multilayer 670. It has been found that first dopant, for example rubidium or silicon, within concentration ranges described above with respect to FIG. 2A, which can be better achieved and maintained with the assistance of the barrier function of layers 144, 148, can increase the free charge carrier concentration in the window layer 130 and multilayer 670 which increases the flow of electric current and improves the overall electrical performance of the device 60.

FIG. 6B shows the device 60 after processing of the cadmium telluride multilayer 670 is completed. Back contact 150 and back support 160, applied in sequence over cadmium telluride multilayer 670, are identical to such layers in the FIG. 2B embodiment.

In general, fabrication of window layer 130 and respective cadmium telluride multilayers 270, 370, 470, 570, 670 can be formed using deposition system 70, as shown in FIG. 7. FIG. 7 illustrates deposition system 70 for processing devices 20, 30, 40, 50, 60 which includes deposition stations 302, 312, 322, 332, 342, each of which may include its own chamber. Alternatively, a single chamber may house depositions stations 302, 312, 322, 332, 342 in delineated areas, in which different materials may be deposited under varying conditions. Each layer of devices 20, 30, 40, 50, 60 may be formed sequentially in respectively designated deposition stations 302, 312, 322, 332, 342 in different stations or in the same station according to the sequence described in the disclosed embodiments.

Deposition stations 302, 312, 322, 332, 342 can be heated to reach a processing temperature in the range of about 450° C. to about 800° C. and can respectively include a deposition distributor connected to a deposition vapor supply. Deposition system 70 can include a conveyor 34, for example a roll conveyor for conveying substrate 100 through deposition stations 302, 312, 322, 332, 342. The conveyor transports the substrate 100, e.g. a soda-lime glass plate, along a transport path and into a series of deposition stations 302, 312, 322, 332, 342 for sequentially depositing layers of material on an exposed surface 32 of substrate 100. Each station 302, 312, 322, 332, 342 may have its own vapor distributor and supply. The distributor can be in the form of one or more vapor nozzles 36 with varying nozzle geometries to achieve uniform distribution of the vapor supply.

By way of example, referring to FIGS. 4A and 7, window layer 130, doped first cadmium telluride layer 142, intrinsic second cadmium telluride layer 144 and at least one doped third cadmium telluride layer 146 can be respectively formed sequentially in deposition stations 302, 312, 322, 332.

It should also be appreciated that substrate 100 depicted in FIGS. 2A, 2B, 3A, 3B, 4A, 4B, 5A, 5B, 6A, 6B and 7 may comprise one or more layers, and may comprise any suitable substrate and base materials. Thus, the deposition system 70 discussed and depicted herein may be part of a larger system for fabricating a photovoltaic device. Prior to or after encountering deposition system 70, the substrate 100 may undergo various other deposition and/or processing steps to form the various layers shown in FIGS. 2A, 2B, 3A, 3B, 4A, 4B, 5A, 5B, 6A, 6B and 7, for example.

Although vapor transport deposition may be employed to form window layer 140 and cadmium telluride multilayers 270, 370, 470, 570, 670, this is not limiting. Other suitable deposition techniques may be used, for example atmospheric pressure chemical vapor deposition, sputtering, atomic layer epitaxy, laser ablation, physical vapor deposition, close-spaced sublimation, electrodeposition, screen printing, spray, or metal organic chemical vapor deposition.

The embodiments described above are offered by way of illustration and example. It should be understood that the examples provided above may be altered in certain respects and still remain within the scope of the claims. It should be appreciated that, while the invention has been described with reference to the above example embodiments, other embodiments are within the scope of the claims. It should also be understood that the appended drawings are not necessarily to scale, presenting a somewhat simplified representation of various features and basic principles of the invention.

1. A photovoltaic device comprising:
a window layer;
a back contact formed over the window layer; and
an absorber multilayer formed between the window layer and the back contact, the absorber multilayer comprising:
a doped first cadmium telluride layer which contains a first dopant; and
an intrinsic second cadmium telluride layer.

2. The photovoltaic device of claim 1, wherein the doped first cadmium telluride layer is formed between the window layer and the intrinsic second cadmium telluride layer.

3. The photovoltaic device of claim 1, wherein the intrinsic second cadmium telluride layer is formed between the window layer and the doped first cadmium telluride layer.

4. The photovoltaic device of claim 1, wherein the first dopant comprises a material selected from the group consisting of lithium, sodium, potassium, rubidium, silicon, germanium, tin, copper, silver, gold, nitrogen, phosphorus, arsenic, antimony, bismuth and a chlorine-containing compound thereof.

5. The photovoltaic device of claim 4, wherein the first dopant comprises rubidium or silicon.

6. (canceled)

7. The photovoltaic device of claim 1, the absorber multilayer further comprising:
at least one third cadmium telluride layer.

8. The photovoltaic device of claim 7, wherein the at least one third cadmium telluride layer is formed between the back contact and the doped first cadmium telluride layer.

9. The photovoltaic device of claim 7, wherein the at least one third cadmium telluride layer is formed between the back contact and the intrinsic second cadmium telluride layer.

10. The photovoltaic device of claim 7, wherein the at least one third cadmium telluride layer contains a second dopant.

11. The photovoltaic device of claim 7, wherein the at least one third cadmium telluride layer comprises intrinsic cadmium telluride.

12. (canceled)

13. The photovoltaic device of claim 10, wherein the second dopant comprises a material selected from the group consisting of copper, silver, gold, nitrogen, phosphorus, arsenic, antimony, bismuth, oxygen and a chlorine-containing compound thereof.

14. The photovoltaic device of claim 13, wherein the second dopant comprises copper.

15. (canceled)

16. A method of forming a photovoltaic device, the method comprising:
forming a window layer over a substrate;
forming an absorber multilayer over the window layer, the absorber multilayer comprising:
a doped first cadmium telluride layer which contains a first dopant; and
an intrinsic second cadmium telluride layer.

17-22. (canceled)

23. The method of claim 16, wherein the step of forming an absorber multilayer over the window layer further comprises forming at least one third cadmium telluride layer.

24. The method of claim 23, wherein the at least one third cadmium telluride layer is formed between the back contact and the doped first cadmium telluride layer.

25-31. (canceled)

32. The method of claim 16, further comprising heating the absorber multilayer at a temperature between about 380° C. and about 800° C. in the presence of cadmium chloride.

33-36. (canceled)

37. The method of claim 16, further comprising heating the photovoltaic device to provide in-situ control of a thickness of the window layer.

38. The method of claim 37, wherein the heating step comprises heating the photovoltaic device at a temperature between about 450° C. and about 800° C.

39. The method of claim 38, wherein the window layer comprises cadmium sulfide, and wherein the heating step further comprises:
reacting the first dopant with cadmium sulfide; and
controlling the window layer thickness to be greater than about 300 angstroms.

40. The method of claim 39, wherein the heating step further comprises:
forming intermediate compounds having melting points of below about 450° C.

41-43. (canceled)
